(19) United States
(12) Patent Application Publication
(10) Pub. No.: US 2025/0379145 A1
(43) Pub. Date: Dec. 11, 2025

(54) STACKED FET WITH BACKSIDE REPLACEMENT METAL GATE

(71) Applicant: INTERNATIONAL BUSINESS MACHINES CORPORATION, Armonk, NY (US)

(72) Inventors: Takashi Ando, Eastchester, NY (US); Reinaldo Vega, Mahopac, NY (US); Ruilong Xie, Niskayuna, NY (US); Nicholas Anthony Lanzillo, Wynantskill, NY (US); David Wolpert, Poughkeepsie, NY (US); James P. Mazza, Saratoga Springs, NY (US)

(21) Appl. No.: 18/736,945

(22) Filed: Jun. 7, 2024

(51) Int. Cl. H01L 23/528; H01L 27/06; H01L 27/092; H01L 29/06; H01L 29/423; H01L 29/775; H01L 29/786

(52) U.S. Cl. CPC H01L 23/5283; H10D 30/43; H10D 30/6735; H10D 30/6757; H10D 62/121; H10D 84/856; H10D 88/00

(57) ABSTRACT

A semiconductor device includes a stacked transistor structure having top field effect transistors stacked on bottom field effect transistors. Top gate structures are associated with the top field effect transistors. Bottom gate structures have backside replacement metal gates (RMGs), which are associated with the bottom field effect transistors such that the bottom gate structures are electrically accessed from a backside of the semiconductor device.

### BACKGROUND

The present invention generally relates to semiconductor devices and processing methods, and more particularly to stacked field effect transistors (FETs) with a backside metal gate.

Stacked transistor devices may be used to increase areal density of devices on a chip. Additionally, the close proximity of the overlying and underlying devices can be useful when forming paired devices, such as complementary semiconductor devices that include two devices of opposing polarity. However, positioning transistors above one another places spatial and electrical constraints that can make it challenging to provide required performance.

### SUMMARY

In accordance with an embodiment of the present invention, a semiconductor device includes a stacked transistor structure having top field effect transistors stacked on bottom field effect transistors. Top gate structures are associated with the top field effect transistors. Bottom gate structures have backside replacement metal gates (RMGs), which are associated with the bottom field effect transistors such that the bottom gate structures are electrically accessed from a backside of the semiconductor device.

In accordance with another embodiment of the present invention, a semiconductor device, includes a top nanosheet device stacked above a bottom nanosheet device. A first work function setting metal of the bottom nanosheet device is different than a second work function setting metal of the top nanosheet device. A portion of the first work function setting metal of the bottom nanosheet device extends through a backside isolation dielectric and directly contacts backside wiring layers.

In accordance with another embodiment of the present invention, a semiconductor device, includes a stacked transistor structure having top field effect transistors stacked on bottom field effect transistors. Top gate structures are associated with the top field effect transistors wherein the top gate structures include a top work function setting metal. Bottom gate structures are associated with the bottom field effect transistors, and the bottom gate structures include a bottom work function setting metal that is different than the top work function setting metal. The bottom gate structures include an extended portion that extends through a bottom dielectric isolation and is further disposed between sacrificial placeholders formed in a semiconductor layer on the backside of the semiconductor device such that the bottom gate structures are electrically accessed from the backside of the semiconductor device.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 shows a cross-sectional view of a stacked (field effect transistor) FET semiconductor device after dummy gate removal, in accordance with an embodiment of the present invention;

FIG. 2 shows a cross-sectional view of the stacked FET semiconductor device after forming a gate dielectric and depositing a fill material in spaces within layers of a nanosheet, in accordance with an embodiment of the present invention;

FIG. 3 shows a cross-sectional view of the stacked FET semiconductor device after opening up the fill material in the spaces on top gate structures, in accordance with an embodiment of the present invention;

FIG. 4 shows a cross-sectional view of the stacked FET semiconductor device after forming a top work function setting metal in the top gate structures, in accordance with an embodiment of the present invention;

FIG. 5 shows a cross-sectional view of the stacked FET semiconductor device after forming middle of the line contacts, forming back end of the line structures and applying a carrier, in accordance with an embodiment of the present invention;

FIG. 6 shows a cross-sectional view of the stacked FET semiconductor device after flipping the wafer and removing a substrate, in accordance with an embodiment of the present invention;

FIG. 7 shows a cross-sectional view of the stacked FET semiconductor device after removing an etch stop layer, in accordance with an embodiment of the present invention;

FIG. 8 shows a cross-sectional view of the stacked FET semiconductor device after recessing a semiconductor layer to expose sacrificial placeholders, in accordance with an embodiment of the present invention;

FIG. 9 shows a cross-sectional view of the stacked FET semiconductor device after recessing the sacrificial placeholders to form recesses, in accordance with an embodiment of the present invention;

FIG. 10 shows a cross-sectional view of the stacked FET semiconductor device after forming protection caps in the recesses, in accordance with an embodiment of the present invention;

FIG. 11 shows a cross-sectional view of the stacked FET semiconductor device after opening the semiconductor layer and a bottom dielectric isolation, in accordance with an embodiment of the present invention;

FIG. 12 shows a cross-sectional view of the stacked FET semiconductor device after opening up the fill material in the spaces on bottom gate structures, in accordance with an embodiment of the present invention;

FIG. 13 shows a cross-sectional view of the stacked FET semiconductor device after forming a bottom work function setting metal in the bottom gate structures and including an extended portion to connect to backside wiring structures, in accordance with an embodiment of the present invention; and

FIG. 14 shows a cross-sectional view of a gate structure showing greater structural detail, in accordance with an embodiment of the present invention.

### DETAILED DESCRIPTION

In accordance with embodiments of the present invention, devices and methods are described which include backside gate structures. Although backside gate structures in accordance with the present embodiments can be employed on any semiconductor device, the backside gate structures are particularly useful in stacked field effect transistor (FET) devices. Matched Work Function (MWF) gate stacks can be employed to achieve individual threshold voltages for PFETs and NFETs. Stacked FET architectures can have PFETs and NFETs at a same layout location on a chip and are stacked vertically. In such instances, masking strategies that may be applicable for structures with PFETs and NFETs at different areal locations of the chip, cannot be employed for stacked FET devices. In accordance with embodiments of the present invention, methods and devices are provided that achieve a reliable Matched Work Function gate stack for stacked FET devices.

In an embodiment, a semiconductor wafer includes a semiconductor device having nanosheet transistors with stacked NFETs and PFETs. The NFETs and PFETs have different work function setting metals for respective gate structures. The work function setting metal of a bottom nanosheet connects to a wafer backside through a bottom dielectric isolation layer. In an embodiment, the work function setting metals can have a dielectric boundary separating between a top-most sheet of a bottom structure and a bottom-most sheet of a top structure. In this way, a top gate and a bottom gate are separately controlled in operation and in fabrication. In this embodiment, the top gate is accessed from a frontside of the device, and a back gate is accessed from a backside of the device. The work function setting metals can have a boundary at a middle isolation region between an NFET and a PFET in a stack.

In the other embodiments, the work function setting metals can contact each other at the middle point. In this embodiment, a top gate and a bottom gate are controlled together with a common contact from a backside of the device (or from a frontside of the device).

In another embodiment, a stacked semiconductor structure includes a top nanosheet device stacked above a bottom nanosheet device. A first work function setting metal of the bottom nanosheet device is different than a second work function setting metal of the top nanosheet device. A portion of the first work function setting metal of the bottom nanosheet device extends through a backside dielectric layer and directly contacts backside wiring layers.

In other embodiments, methods for fabricating a stacked FET device include forming a nanosheet device with sacrificial placeholders associated with bottom source/drain regions. A gate dielectric layer is formed over nanosheet channel. An optional dipole layer can be included on the gate dielectric. A cap layer and sacrificial fill, such as amorphous Si, can be formed and a reliability anneal can be performed. The sacrificial fill can be recessed from a frontside to a middle dielectric isolation (MDI) layer. In an embodiment, a P-type work function metal (or an N-type work function metal) can be deposited followed by a metal fill (e.g., W) from the frontside. A planarization process levels off excess material. Then, the wafer can be flipped to work on the backside of the device.

A substrate is removed from the backside and an interlayer dielectric is formed thereon. Sacrificial placeholders are vertically recessed and a cap deposition is performed to fill in the recess. A planarization process is performed to remove excess cap material. The interlayer dielectric is opened up by a backside etch using the caps for self-alignment. A bottom dielectric isolation is opened and a dummy gate material is removed. An N-type work function metal (or a P-type work function metal) can be employed as a fill to provide a gate conductor for the bottom gate. A planarization process is performed to remove excess metal material. Optionally, self-aligned backside contacts can be formed to connect to the gate conductor of the bottom gate. A backside power distribution network can be fabricated on the backside of the device.

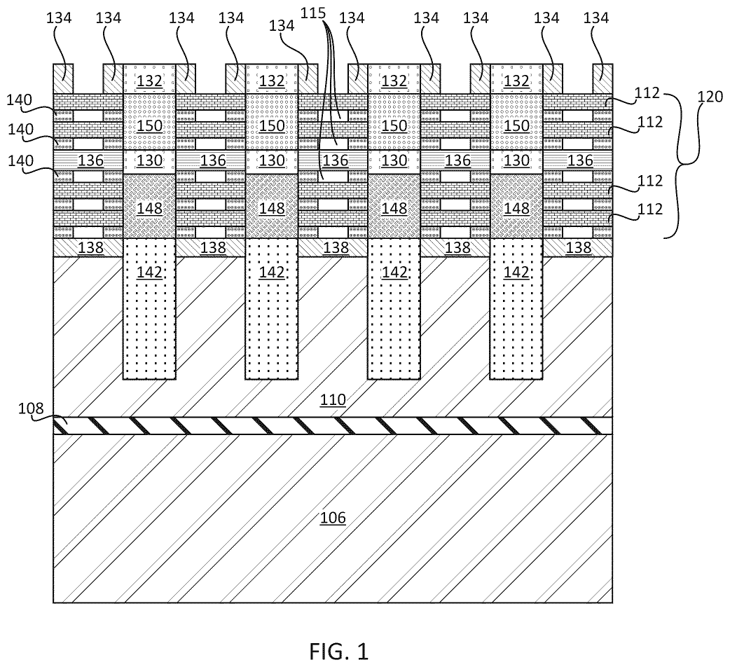

Referring now to the drawings in which like-numerals represent the same or similar elements and initially to FIG. 1, devices and methods for manufacturing a stacked field effect transistor (FET) device are shown in accordance with embodiments of the present invention. A wafer 100 includes a substrate 106 having one or more layers on which the stacked FET device will be fabricated. The substrate 106 can include any suitable substrate structure, e.g., a bulk semiconductor, a semiconductor-on-insulator (SOI) substrate, etc., and preferably includes a monocrystalline semiconductor. In one example, the substrate 106 can include a silicon-containing material. Illustrative examples of Si-containing materials suitable for the substrate 106 can include, but are not limited to, Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, etc.

An etch stop layer 108 is formed on the substrate 106. The etch stop layer 108 can include an epitaxially grown crystal structure. The etch stop layer 108 includes a material that permits the selective etching and removal the substrate 106 in later steps. In one embodiment, the etch stop layer 108 includes SiGe although depending on the material of the substrate 106, other materials can be selected, e.g., SiGeC, SiC, etc.

A semiconductor layer 110 is epitaxially grown on the etch stop layer 108. The semiconductor layer 110 can include a same material as the substrate 106, although other semiconductor materials can be employed, e.g., SiGe, SiGeC, SiC, etc. One or more nanosheets (NS) are applied to the semiconductor layer 110.

In an embodiment, a nanosheet 120 includes semiconductor layers provided in an alternating pattern. Semiconductor layers 112 can be employed as device channels and can include, e.g., Si. Spaces 115 are depicted where alternating semiconductor layers have been selectively removed and temporarily filled with dummy gate material. FIG. 1 depicts the wafer 100 after the dummy gate material has been removed prior to replacement with a metal gate material.

The semiconductor layer 110 can be etched to form shallow trenches therein. Shallow trench isolation (STI) or STI regions (not shown) are then formed in the etched trenches.

Prior to the removal of the dummy gate material, a deposition process forms spacers 134, middle dielectric isolation (MDI) 136 and bottom dielectric isolation (BDI) 138 to fill empty regions where semiconductor layers of the nanosheet 120 were removed. Spacers 134, MDI 136 and BDI 138 can include an oxide, such as silicon dioxide, a nitride, such as silicon nitride, although other dielectric materials can be employed.

Inner spacers 140 are also formed and include a dielectric material. In an embodiment, the inner spacers 140 are formed by recessing the now-removed semiconductor layer at locations of the spaces 115 and filling in the recesses with a dielectric material, such as e.g., a silicon nitride (SiN).

The semiconductor layer 110 was recessed to form trenches, e.g., by reactive ion etching (RIE). Within the trenches recessed into the semiconductor layer 110, sacrificial placeholders 142 are formed. The sacrificial placeholders 142 can be epitaxially grown in the trenches of semiconductor layer 110. The sacrificial placeholders 142 can include SiGe or other epitaxial grown material that can be selectively removed relative to the semiconductor layer 110.

Epitaxial growth processes are performed to grow bottom source/drain regions 148 and top source/drain regions 150. The bottom source/drain regions 148 are employed for bottom transistors of the stacked FET device under construction. The bottom source/drain regions 148 can include Si or SiGe. In an embodiment, the bottom source/drain regions 148 can be designated as P-type or N-type devices. If the bottom source/drain regions 148 include N-type devices than the bottom source/drain regions 148 can include Si. If the bottom source/drain regions 148 include P-type devices than the bottom source/drain regions 148 can include SiGe. The bottom source/drain regions 148 can be appropriately doped during the formation of the bottom source/drain regions 148 by epitaxial growth. For example, the bottom source/drain regions 148 can be doped by introducing p dopants (e.g., B, Ga, etc.) during epitaxial formation. Similarly, the bottom source/drain regions 148 can be doped by introducing n dopants (e.g., P, As, etc.) during epitaxial formation.

The top source/drain regions 150 can be similarly formed as NFETs or PFETs. Regions are protected in a top region when the bottom source/drain regions 148 are formed (e.g., by depositing a protective dielectric liner over the semiconductor layer 112 (which forms channels)). A dielectric plug 130 (e.g., an oxide or nitride) is formed on the bottom source/drain regions 148 so that the top source/drain regions 150 can be grown.

The top source/drain regions 150 are employed for top transistors of the stacked FET device under construction. The top source/drain regions 150 can include Si or SiGe. In an embodiment, the top source/drain regions 150 can be designated as P-type or N-type devices. If the top source/drain regions 150 include N-type devices than the top source/drain regions 150 can include Si. If the top source/drain regions 150 include P-type devices than the top source/drain regions 150 can include SiGe. The top source/drain regions 150 can be appropriately doped during the formation of the top source/drain regions 150 by epitaxial growth. For example, the top source/drain regions 150 can be doped by introducing p dopants (e.g., B, Ga, etc.) during epitaxial formation. Similarly, the top source/drain regions 150 can be doped by introducing n dopants (e.g., P, As, etc.) during epitaxial formation. Another dielectric plug 130 (e.g., an oxide or a nitride) is formed over the top source/drain regions 150 to protect the top source/drain regions 150 from further processing.

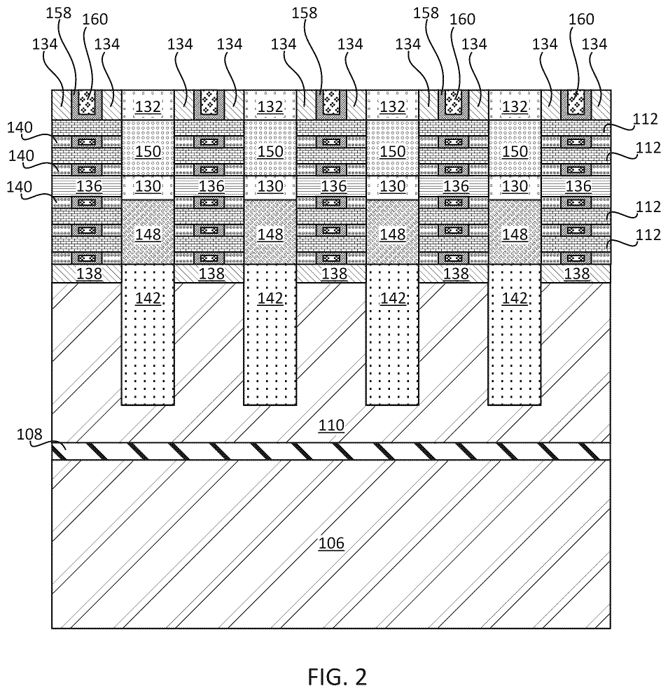

Referring to FIG. 2, the wafer 100 is subjected to a high dielectric constant (high-K) material deposition which lines the semiconductor layers 112 and surfaces within spaces 115 (FIG. 1). The high-K material includes a high-K gate dielectric 158, which is formed over the semiconductor layers 112, the spacers 118 and other exposed surfaces.

The high-K gate dielectric 158 can include a metal oxide, such as, hafnium oxide (HfO), hafnium silicon oxide (HfSiO), hafnium silicon oxynitride (HfSiON), lanthanum oxide (LaO), lanthanum aluminum oxide (LaAlO), zirconium oxide (ZrO), zirconium silicon oxide (ZrSiO), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO) and aluminum oxide (AlO). The high-K material may further include dopants such as lanthanum, aluminum, magnesium, or combinations thereof. In a particularly useful embodiment, high-K gate dielectric 158 includes HfO₂. The high-K gate dielectric 158 can be deposited by chemical vapor deposition (CVD) or other suitable deposition process. The high-K gate dielectric 158 can include a dipole layer formed therein or thereon.

After the high-K gate dielectric 158 is formed, a capping layer (not shown) is formed on the high-K gate dielectric 158. The capping layer can include TiN, TaN, or other suitable materials. A fill material 160 is deposited within the spaces 115 (FIG. 1) to fill the spaces 115 for an anneal process. In an embodiment, the fill material 160 can include amorphous Si, although other dielectric fill materials can also be employed.

An anneal process is performed. The anneal process can include a reliability anneal (e.g., greater than 900° C.). A reliability anneal can be employed to address negative bias temperature instability (NBTI) for PFET devices by improving dielectric quality (densification). A planarization process, such as chemical mechanical polishing (CMP), is performed to remove excess material from a free surface of the wafer 100.

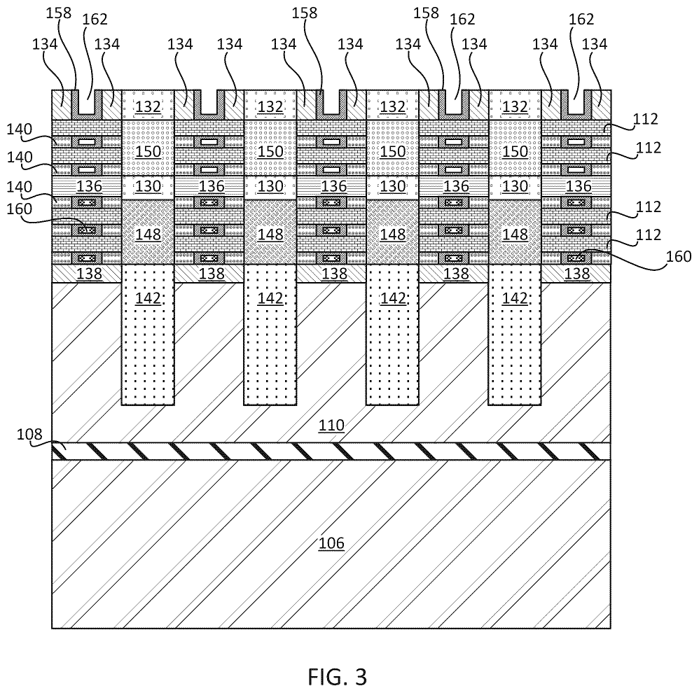

Referring to FIG. 3, the fill material 160 is recessed from a frontside of the wafer 100. The fill material 160 is recessed using an isotropic etch process, such as, e.g., a wet etch. The fill material 160 is removed down to the MDI 136 to open up spaces 162 for a top gate conductor to be formed in later steps. The fill material 160 is etched selectively with respect to the high-K gate dielectric 158 or the capping layer, if present. The capping layer, if present, can also be optionally removed above (e.g., toward the top) the MDI 136.

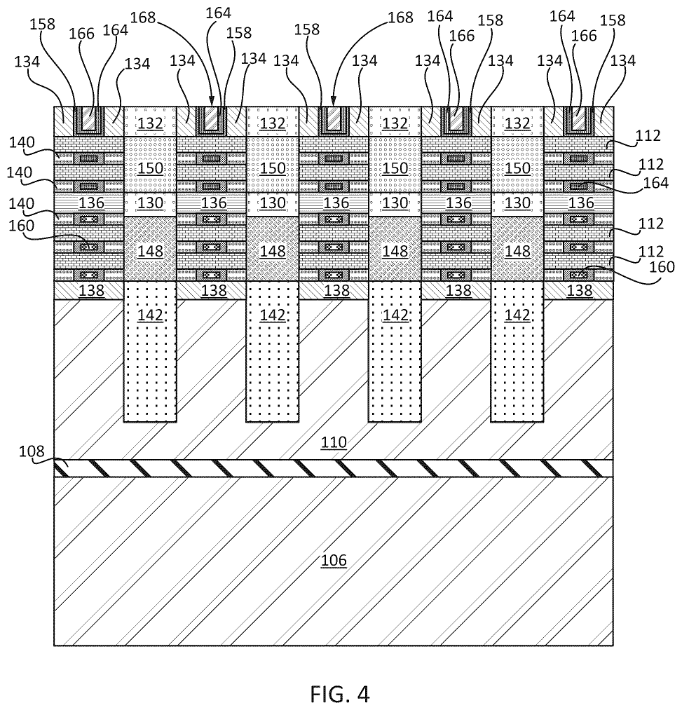

Referring to FIG. 4, a top work function metal (TWFM) 164 (also referred to as a top work function setting metal) is deposited over the high-K gate dielectric 158 (or capping layer, if present). The TWFM 164 can include a p-type work function metal or an n-type work function metal. A p-type work function metal includes a metal layer that effectuates a p-type threshold voltage shift. A threshold voltage is the lowest attainable gate voltage that will turn on a semiconductor device, e.g., transistor, by making the channel of the device conductive. In an embodiment, the p-type work function metal can include titanium and their nitrides/carbides, e.g., the p-type work function metal can include titanium nitride (TiN). The p-type work function metal may also include W, Ru, Pt, Mo, Co and alloys and combinations thereof. The p-type work function metal may be deposited by a physical vapor deposition (PVD) method, such as sputtering, chemical vapor deposition (CVD) or atomic layer deposition (ALD).

In some embodiments, the TWFM 164 can include an n-type work function metal. The n-type work function metal layer is a metal layer that effectuates an n-type threshold voltage shift. In an embodiment, the n-type work function metal layer can include TiAl, TaN, TiN, HfN, HfSi, or combinations thereof. The n-type work function metal can be deposited using CVD, ALD, sputtering or plating.

After the TWFM 164 is formed, a gate metal fill 166 is provided to complete top gate structures 168. The gate metal fill 166 can include any conductive metal including, but not limited to W, Ni, Ti, Mo, Ta, Cu, Pt, Ag, Au, Ru, Ir, Rh, and Re, and alloys that include at least one of these conductive materials. The gate metal fill 166 can include one or more layers of conductive materials. In one example, a second conductive material may be formed. When a combination of conductive elements is employed, an optional diffusion barrier material such as TaN or WN may be formed between the conductive materials. The gate metal fill 166 can be deposited by CVD, plasma enhanced CVD (PECVD), ALD or other suitable deposition process. A planarization process, such as CMP, is performed to remove excess material from the free surface of the wafer 100.

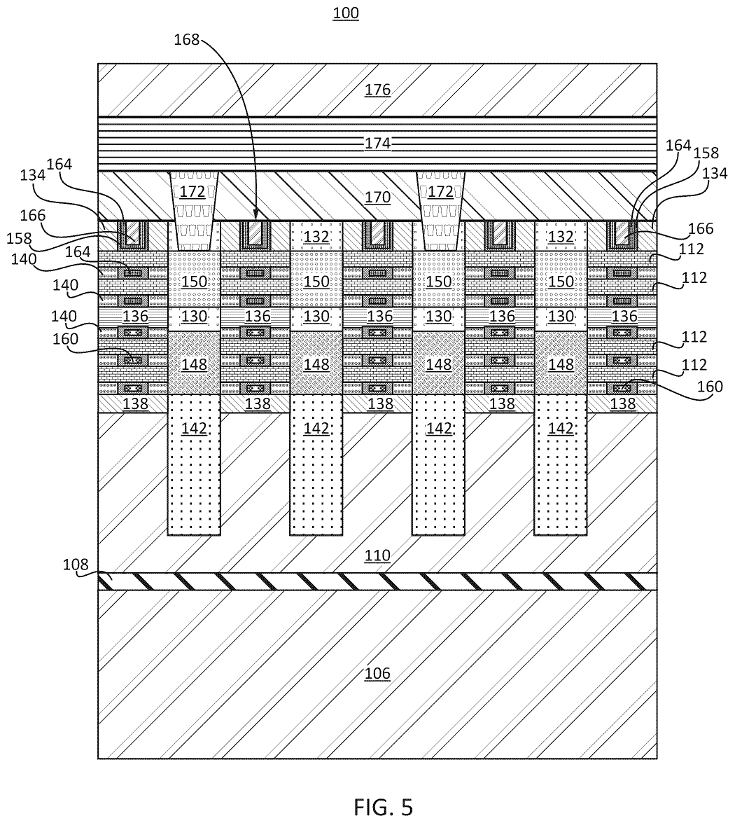

Referring to FIG. 5, an interlayer dielectric (ILD) 170 is deposited over the wafer 100. The ILD 170 can include any suitable material, e.g., a silicon containing material(s) such as SiO₂, Si₃N₄, SiOₓN_{y}, SiC, SiCO, SiCOH, and SiCH compounds, the above-mentioned silicon containing materials with some or all of the Si replaced by Ge, carbon doped oxides, inorganic oxides, inorganic polymers, hybrid polymers, organic polymers such as polyamides or SiLK™, other carbon containing materials, organo-inorganic materials such as spin-on glasses and silsesquioxane-based materials, and diamond-like carbon (DLC), also known as amorphous hydrogenated carbon, α-C:H). The ILD 170 can be deposited using CVD, although other deposition methods can be employed.

Middle of the line (MOL) contacts 172 are formed to make connections with the top source/drain regions 150 from a top side of the wafer 100. Gate contacts (not shown) can also be formed to connect to the gate metal fill 166 of the top gate structures 168. Trenches or holes are formed in the ILD 170 to expose the underlying active materials for the top source/drain regions 150.

In some embodiments, a silicide liner, such as Ti, Ni, NiPt is deposited first in the trenches or holes, then a diffusion barrier can be formed in the trenches or holes prior to a conductive fill. The diffusion barrier can include, e.g., TiN, TaN, or similar materials.

A conductive fill is performed to fill the trenches or hole on top of the diffusion barrier, if present. The conductive fill can include materials, such as, e.g., Cu, Ru, Mo, Rh, W, Ir, and alloys or combinations of these and other conductive materials. In a particularly useful embodiment, the conductive fill includes Cu. The conductive fill can be formed using a deposition method, such as, e.g., CVD, PECVD, ALD or any other suitable deposition method. The conductive fill is planarized, e.g., by CMP, to form the MOL contacts 172.

Processing continues with the formation of a back end of the line (BEOL) layer 174, which can include metal structures and dielectric layers to complete the top side of the stacked FET device and provide electrical access to the devices formed. A carrier wafer 176 can be bonded to the BEOL layer 174. The carrier wafer 176 provides support and transportability to the wafer 100 for further processing which includes flipping the wafer 100 and removing portions of a bottom side of the wafer 100 to fabricate the stacked FET device.

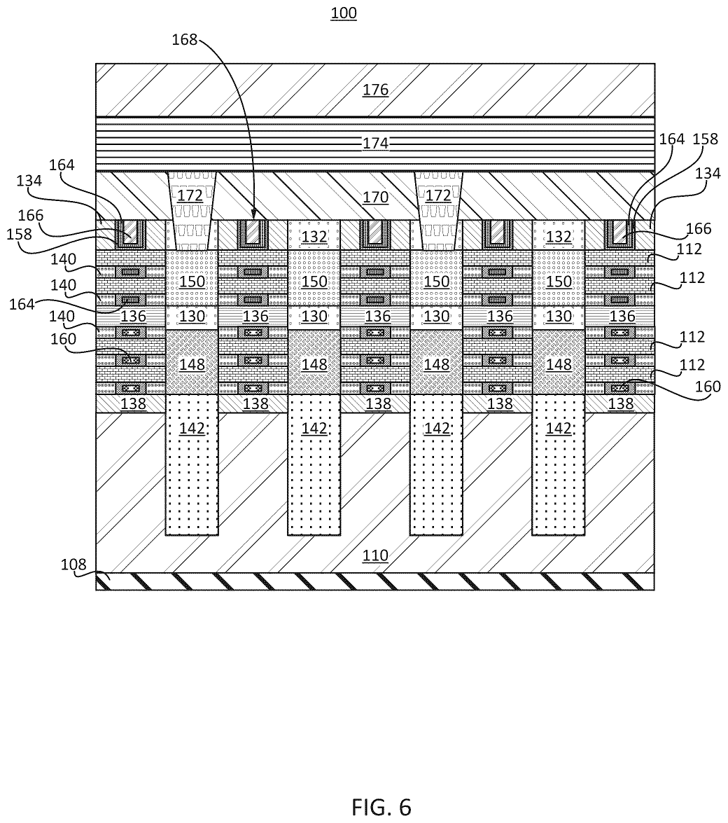

Referring to FIG. 6, to continue processing, the wafer 100 can be flipped to process features on the bottom side of the wafer 100 to form the stacked FET device. However, for clarity and consistency, the stacked FET device will be shown in the FIGS. in a same orientation as previously described with continued and consistent reference to bottom/top (backside/frontside). The substrate 106 is removed from the bottom side of the stacked FET device. The substrate 106 can be removed by an etch process that stops on the etch stop layer 108.

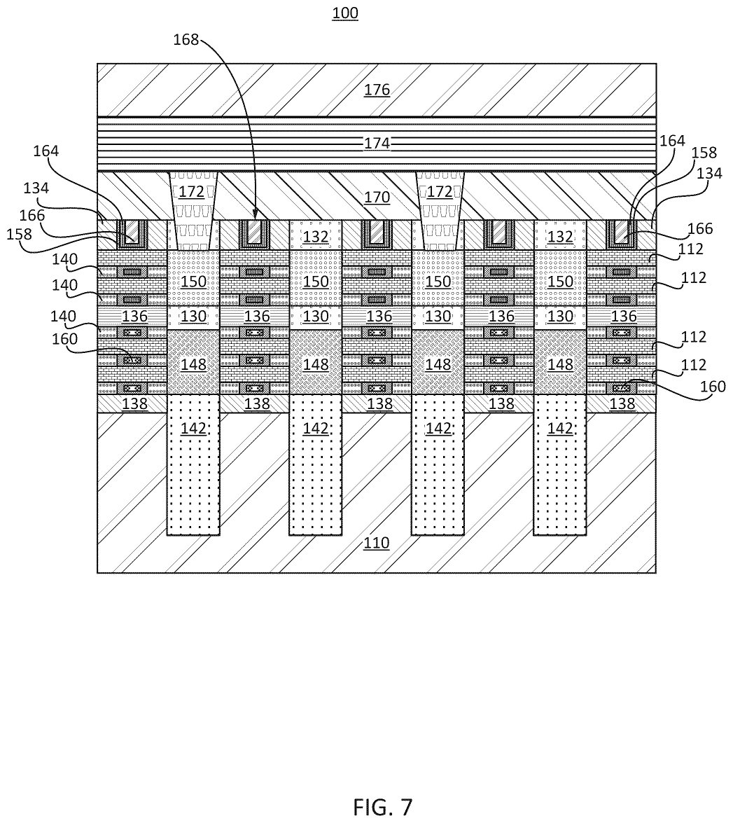

Referring to FIG. 7, the etch stop layer 108 is then removed by an etch process. In an alternate embodiment, a CMP process can be employed. With the removal of the etch stop layer 108, the semiconductor layer 110 is exposed for further processing.

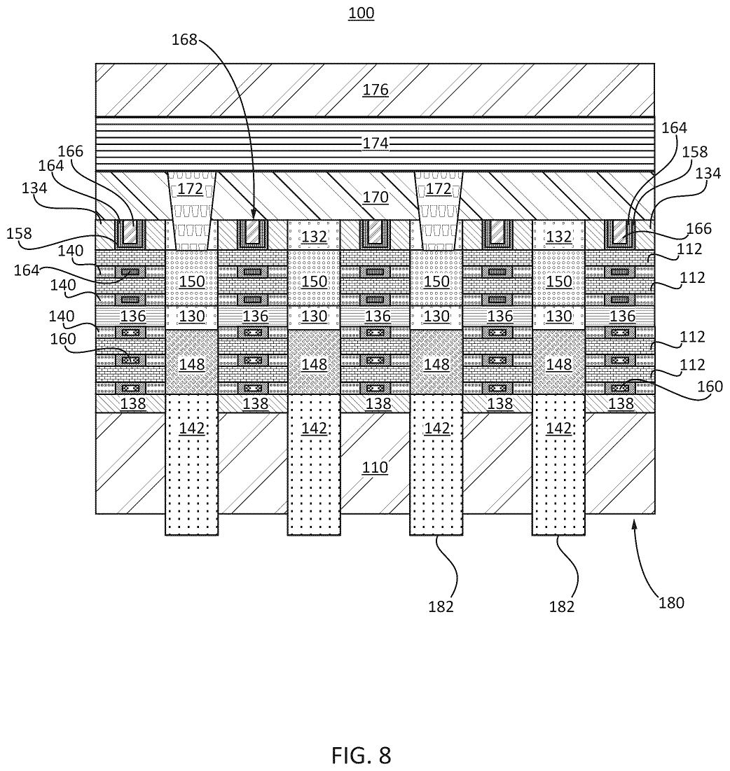

Referring to FIG. 8, the semiconductor layer 110 is recessed on a backside by a partial etch back process that selectively etches the semiconductor layer 110 relative to the sacrificial placeholders 142. A recess 180 is formed, which exposes a portion 182 of the sacrificial placeholders 142. The partial etch back process can include a wet or dry etch.

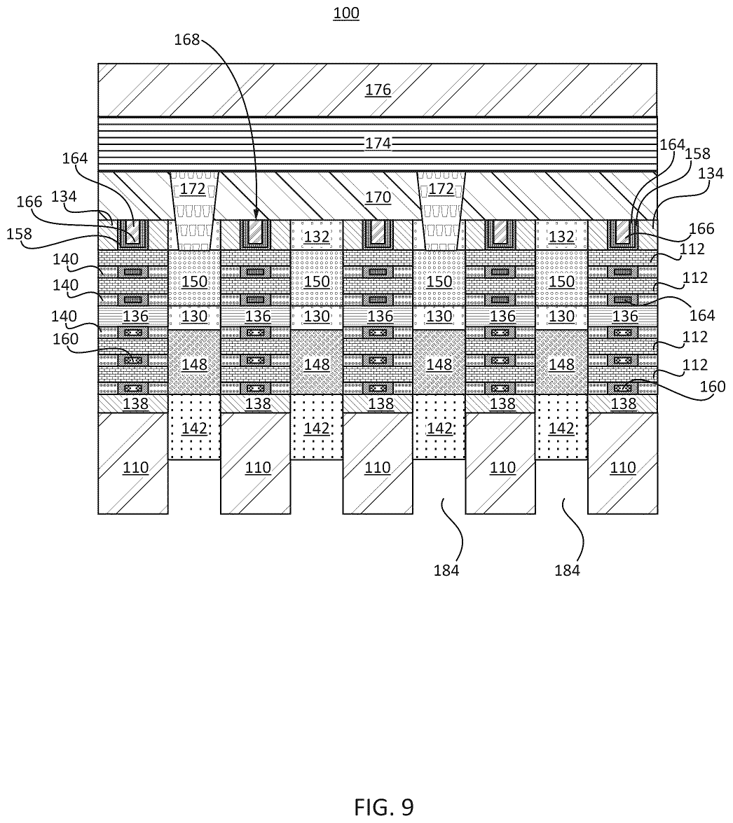

Referring to FIG. 9, the sacrificial placeholders 142 are now recessed relative to the semiconductor layer 110 by a partial etch back process that selectively etches the sacrificial placeholders 142 relative to the semiconductor layer 110. Recesses 184 are formed. The partial etch back process can include a wet or dry etch.

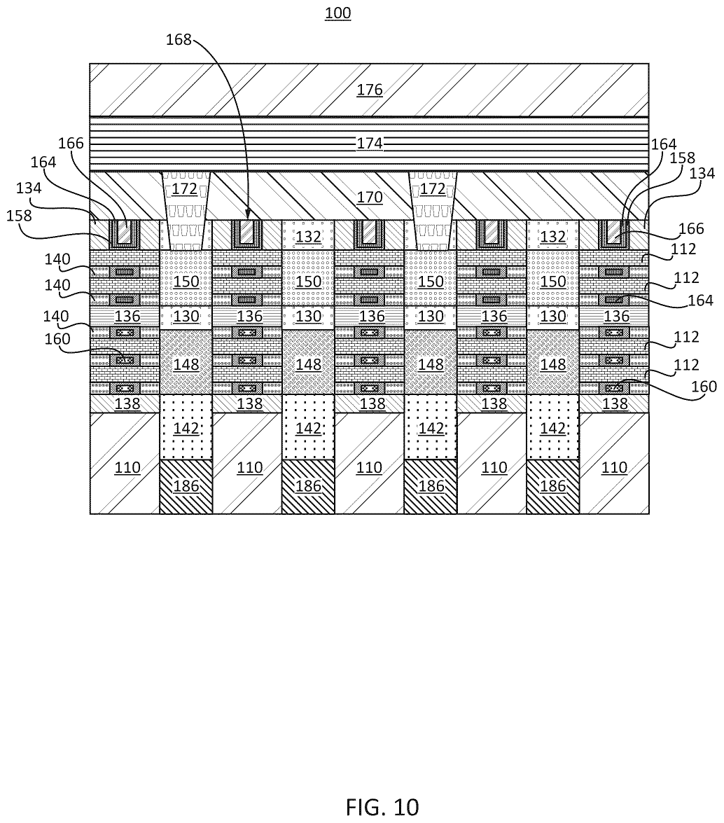

Referring to FIG. 10, a dielectric layer is deposited and planarized to form protection caps 186 within the recesses 184 (FIG. 9). The protection caps 186 include a dielectric material that can permit etching of the semiconductor layer 110 without damage to the sacrificial placeholders 142. In an embodiment, the protection caps 186 can include AlO, SiC, SiCO or any other suitable dielectric material.

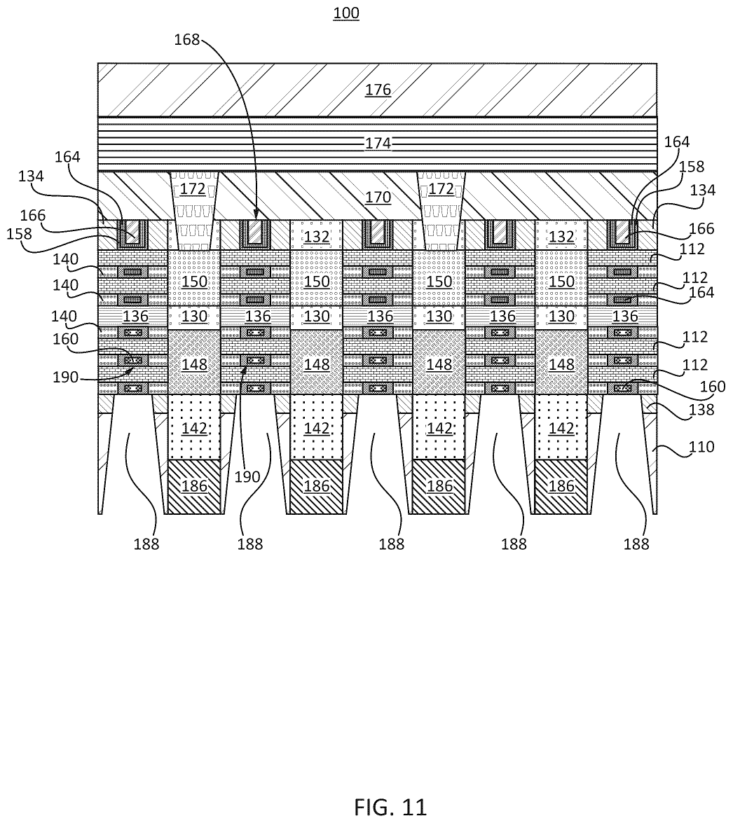

Referring to FIG. 11, a patternable material (not shown) is deposited or spun onto a surface of the backside of the wafer 100. In an embodiment, a layer of photoresist (not shown) is formed. The layer of photoresist can be imaged with an image pattern and developed to form an etch mask. The semiconductor layer 110 can be etched in accordance with the etch mask to open up trenches 188 in the semiconductor layer 110 and open the BDI 138 to access the fill material 160 in bottom gate structures 190. The trenches 188 can be etched by an anisotropic etch, e.g., a RIB etch or ion bean etch (IBE).

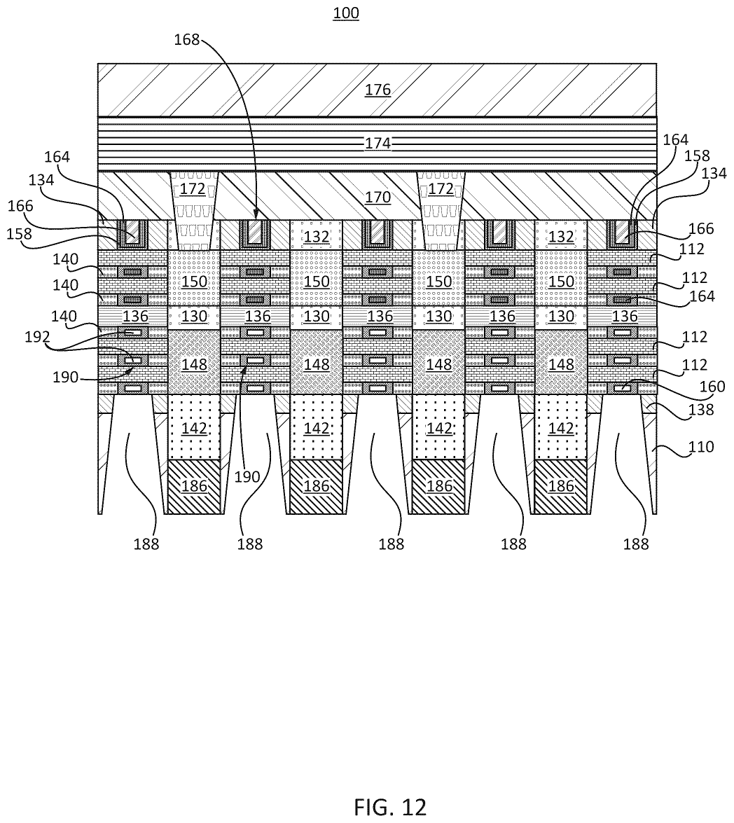

Referring to FIG. 12, the fill material 160 is recessed from a backside of the wafer 100. The fill material 160 is recessed using an isotropic etch process, such as, e.g., a wet etch. The fill material 160 is removed up to the MDI 136 to open up spaces 192 for a bottom gate conductor to be formed in later steps. The fill material 160 is etched selectively with respect to the high-K gate dielectric 158 or the capping layer, if present. The capping layer, if present, can also be optionally removed below the MDI 136.

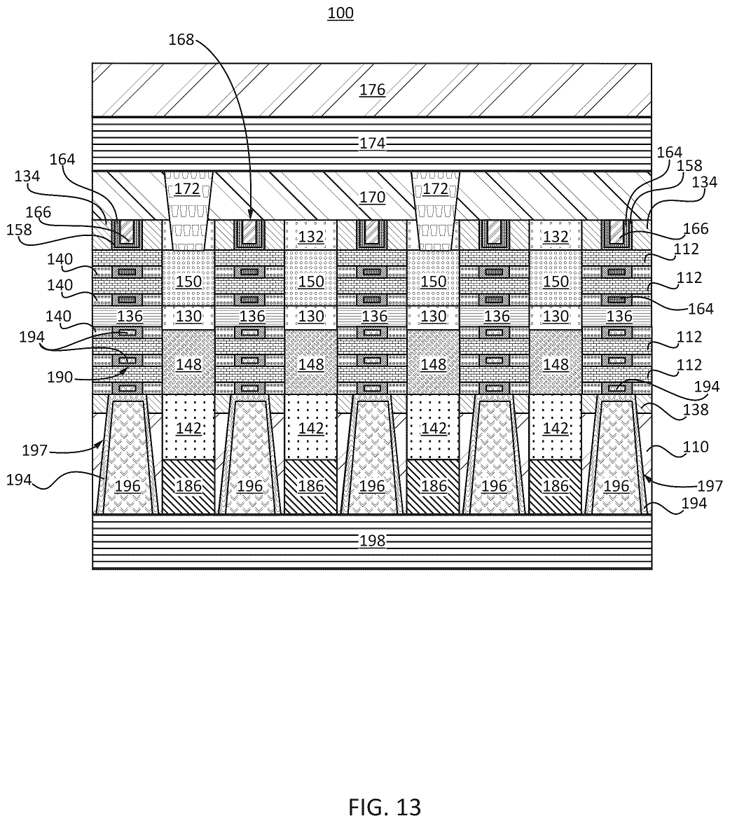

Referring to FIG. 13, a bottom work function metal (BWFM) 194 (also referred to as a bottom work function setting metal) is deposited over the high-K gate dielectric 158 (or capping layer, if present). The BWFM 194 can include a p-type work function metal or an n-type work function metal. In an embodiment, the bottom work function metal (BWFM 194) is opposite in conductivity from the top work function metal (TWFM 164).

A p-type work function metal includes a metal layer that effectuates a p-type threshold voltage shift. In an embodiment, the p-type work function metal can include titanium and their nitrides/carbides, e.g., the p-type work function metal can include titanium nitride (TiN). The p-type work function metal may also include W, Ru, Pt, Mo, Co and alloys and combinations thereof. The p-type work function metal may be deposited by a PVD method, such as sputtering, CVD or ALD.

In some embodiments, the BWFM 194 can include an n-type work function metal. The n-type work function metal layer is a metal layer that effectuates an n-type threshold voltage shift. In an embodiment, the n-type work function metal layer can include TiAl, TaN, TiN, HfN, HfSi, or combinations thereof. The n-type work function metal can be deposited using CVD, ALD, sputtering or plating.

After the BWFM 194 is formed, a gate metal fill 196 is provided to complete the bottom gate structures 190. The gate metal fill 196 is disposed in an extended portion 197, which is disposed between columns of the protection caps 186 and the sacrificial placeholders 142. The gate metal fill 196 can include any conductive metal including, but not limited to W, Ni, Ti, Mo, Ta, Cu, Pt, Ag, Au, Ru, Ir, Rh, and Re, and alloys that include at least one of these conductive materials. The gate metal fill 196 can include one or more layers of conductive materials. In one example, a second conductive material may be formed. When a combination of conductive elements is employed, an optional diffusion barrier material such as TaN or WN may be formed between the conductive materials. The gate metal fill 196 can be deposited by CVD, PECVD, ALD or other suitable deposition process. A planarization process, such as CMP, is performed to remove excess material from the free surface of the wafer 100.

Processing continues with the formation of a backside interconnect layer 198, which can include metal structures and dielectric layers to complete the bottom side of the stacked FET device and provide electrical access to the devices formed. The backside interconnect layer 198 can include a backside power distribution network (BSPDN). The stacked FET device includes a stacked transistor structure having field effect transistors on at least two levels. The at least two levels include a frontside or top and backside or bottom.

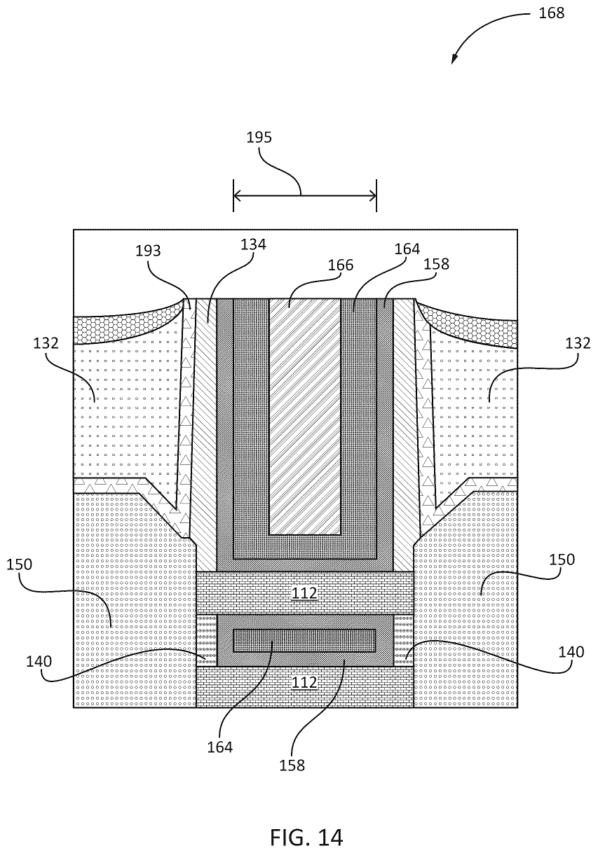

Referring to FIG. 14, a cross-sectional view of the top gate structure 168 is shown in greater detail. The top gate structure 168 and the bottom gate structure 190 can include a same structure. In an embodiment, components, layer thicknesses and materials employed for the top gate structure 168 can be different than those for the bottom gate structure 190. For example, the TWFM 164 and BWFM 194 can include a different thickness and can include a different material. The capping layer, if included, can be disposed between the gate dielectric 158 and the TWFM 164. A dielectric liner 193 (e.g., a POC liner) can be employed over the source/drain regions 150 and over the spacers 134.

The ability to scale a gate length (L_{g}) 195 is dependent upon an integration flow of the work function metals (TWFM 164 and BWFM 194). A conventional integration flow requires deposition of a bottom metal, followed by partial recess of bottom metal and deposition of a top metal. This requires extra space and limits the ability to scale L_{g}. On the other hand, by accessing the bottom gate structures 190 from a backside of the wafer 100, the bottom gate structures 190 are independently constructed. This enables further scaling of L_{g}. Said differently, the bottom gate structures 190 are backside replacement metal gates (RMGs). The backside RMGs are processed from a backside of the wafer 100 to enable L_{g} scaling, among other things. In addition, electrical access is also made to these backside RMG structures from the backside of the device.

Exemplary applications/uses to which the present invention can be applied include, but are not limited to semiconductor devices. Semiconductor devices can include processors, memory devices, application specific integrated circuits (ASICs), logic circuits or devices, combinations of these and any other circuit device. In such devices, one or more semiconductor devices can be included in a central processing unit, a graphics processing unit, and/or a separate processor- or computing element-based controller (e.g., logic gates, etc.). The semiconductor devices can include one or more on-board memories (e.g., caches, dedicated memory arrays, read only memory, etc.). In some embodiments, the semiconductor devices can include one or more memories that can be on or off board or that can be dedicated for use by a hardware processor subsystem (e.g., ROM, RAM, basic input/output system (BIOS), etc.).

In some embodiments, the semiconductor devices can include and execute one or more software elements. The one or more software elements can include an operating system and/or one or more applications and/or specific code to achieve a specified result. In still other embodiments, the semiconductor devices can include dedicated, specialized circuitry that perform one or more electronic processing functions to achieve a specified result. Such circuitry can include one or more field programmable gate arrays (FPGAs), and/or programmable applications programmable logic arrays (PLAs).

It is to be understood that aspects of the present invention will be described in terms of a given illustrative architecture; however, other architectures, structures, substrate materials and process features and steps can be varied within the scope of aspects of the present invention.

It will also be understood that when an element such as a layer, region or substrate is referred to as being “on” or “over” another element, it can be directly on the other element or intervening elements can also be present. In contrast, when an element is referred to as being “directly on” or “directly over” another element, there are no intervening elements present. It will also be understood that when an element is referred to as being “connected” or “coupled” to another element, it can be directly connected or coupled to the other element or intervening elements can be present. In contrast, when an element is referred to as being “directly connected” or “directly coupled” to another element, there are no intervening elements present.

The present embodiments can include a design for an integrated circuit chip, which can be created in a graphical computer programming language, and stored in a computer storage medium (such as a disk, tape, physical hard drive, or virtual hard drive such as in a storage access network). If the designer does not fabricate chips or the photolithographic masks used to fabricate chips, the designer can transmit the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the chip design in question that are to be formed on a wafer. The photolithographic masks are utilized to define areas of the wafer (and/or the layers thereon) to be etched or otherwise processed.

Methods as described herein can be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip is mounted in a single chip package (such as a plastic carrier, with leads that are affixed to a motherboard or other higher level carrier) or in a multichip package (such as a ceramic carrier that has either or both surface interconnections or buried interconnections). In any case, the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

It should also be understood that material compounds will be described in terms of listed elements, e.g., SiGe. These compounds include different proportions of the elements within the compound, e.g., SiGe includes SiₓGe₁₋ₓ where x is less than or equal to 1, etc. In addition, other elements can be included in the compound and still function in accordance with the present principles. The compounds with additional elements will be referred to herein as alloys. Reference in the specification to “one embodiment” or “an embodiment”, as well as other variations thereof, means that a particular feature, structure, characteristic, and so forth described in connection with the embodiment is included in at least one embodiment. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This can be extended, as readily apparent by one of ordinary skill in this and related arts, for as many items listed.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements and/or components, but do not preclude the presence or addition of one or more other features, integers, steps, operations, elements, components and/or groups thereof.

Spatially relative terms, such as “beneath,” “below,” “lower,” “above,” “upper,” “top,” “bottom” and the like, can be used herein for ease of description to describe one element's or feature's relationship to another element(s) or feature(s) as illustrated in the FIGS. It will be understood that the spatially relative terms are intended to encompass different orientations of the device in use or operation in addition to the orientation depicted in the FIGS. For example, if the device in the FIGS. is turned over, elements described as “below” or “beneath” other elements or features would then be oriented “above” the other elements or features. Thus, the term “below” can encompass both an orientation of above and below. The device can be otherwise oriented (rotated 90 degrees or at other orientations), and the spatially relative descriptors used herein can be interpreted accordingly. In addition, it will also be understood that when a layer is referred to as being “between” two layers, it can be the only layer between the two layers, or one or more intervening layers can also be present.

It will be understood that, although the terms first, second, etc. can be used herein to describe various elements, these elements should not be limited by these terms. These terms are only used to distinguish one element from another element. Thus, a first element discussed below could be termed a second element without departing from the scope of the present concept.

Having described preferred embodiments of devices and methods (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a stacked transistor structure having top field effect transistors stacked on bottom field effect transistors;
top gate structures associated with the top field effect transistors; and
bottom gate structures having backside replacement metal gates (RMGs), which are associated with the bottom field effect transistors such that the bottom gate structures are electrically accessed from a backside of the semiconductor device.

2. The semiconductor device as recited in claim 1, wherein the top gate structures include a top work function setting metal, and the bottom gate structures include a bottom work function setting metal different from the top work function setting metal.

3. The semiconductor device as recited in claim 1, wherein the top gate structures include a work function setting metal having a first thickness, and the bottom gate structures include a work function setting metal having a second thickness different from the first thickness.

4. The semiconductor device as recited in claim 1, wherein the bottom gate structures include an extended portion that extends through a bottom dielectric isolation and are further disposed between sacrificial placeholders formed in a semiconductor layer on the backside of the semiconductor device.

5. The semiconductor device as recited in claim 4, further comprising protection caps disposed on the sacrificial placeholders between extended portions of the bottom gate structures.

6. The semiconductor device as recited in claim 4, wherein the extended portion of the bottom gate structures connect to a backside interconnect layer.

7. The semiconductor device as recited in claim 1, wherein the top gate structures include a p-type work function setting metal, and the bottom gate structures include an n-type work function setting metal.

8. The semiconductor device as recited in claim 1, wherein the top gate structures and the bottom gate structures include a metal fill on work function setting metals within the top gate structures and the bottom gate structures.

9. The semiconductor device as recited in claim 8, wherein the metal fill includes a same material for the top gate structures and the bottom gate structures.

10. A semiconductor device, comprising:
a top nanosheet device stacked above a bottom nanosheet device;
a first work function setting metal of the bottom nanosheet device being different than a second work function setting metal of the top nanosheet device; and
a portion of the first work function setting metal of the bottom nanosheet device extending through a bottom dielectric isolation and directly contacting backside wiring layers.

11. The semiconductor device as recited in claim 10, wherein the first work function setting metal has a first thickness, and the second work function setting metal has a second thickness different from the first thickness.

12. The semiconductor device as recited in claim 10, wherein the bottom nanosheet device includes a bottom gate structure having an extended portion that extends through the bottom dielectric isolation and between sacrificial placeholders formed in a semiconductor layer on a backside of the semiconductor device.

13. The semiconductor device as recited in claim 12, further comprising protection caps disposed on the sacrificial placeholders.

14. The semiconductor device as recited in claim 12, wherein the extended portion of the bottom gate structure connects to a backside interconnect layer.

15. The semiconductor device as recited in claim 10, wherein the top nanosheet device includes a top gate structure having a p-type work function setting metal for the second work function setting metal, and the bottom nanosheet device includes a bottom gate structure having an n-type work function setting metal for the first work function setting metal.

16. The semiconductor device as recited in claim 10, further comprising a metal fill disposed on the first work function setting metal of the bottom nanosheet device and the second work function setting metal of the bottom nanosheet device.

17. The semiconductor device as recited in claim 16, wherein the metal fill is a same material on the first work function setting metal and on the second work function setting metal.

18. A semiconductor device, comprising:
a stacked transistor structure having top field effect transistors stacked on bottom field effect transistors;
top gate structures associated with the top field effect transistors wherein the top gate structures include a top work function setting metal;
bottom gate structures associated with the bottom field effect transistors and the bottom gate structures including a bottom work function setting metal that is different than the top work function setting metal; and
the bottom gate structures include an extended portion that extends through a bottom dielectric isolation and are further disposed between sacrificial placeholders formed in a semiconductor layer on a backside of the semiconductor device such that the bottom gate structures are electrically accessed from the backside of the semiconductor device.

19. The semiconductor device as recited in claim 18, wherein the top work function setting metal has a thickness that is different than the bottom work function setting metal.

20. The semiconductor device as recited in claim 18, wherein the top gate structures and the bottom gate structures include a metal fill on work function setting metals within the top gate structures and the bottom gate structures.
